(19) United States
(12) Patent Application Publication
(10) Pub. No.: US 2007/0120207 A1
(43) Pub. Date: May 31, 2007

(54) Torsion spring for MEMS structure

(75) Inventors: Hee-moon Jeong, Yongin-si (KR); Young-chul Ko, Yongin-si (KR)

Correspondence Address: SUGHRUE MION, PLLC, 2100 PENNSYLVANIA AVENUE, N.W., SUITE 800, WASHINGTON, DC, 20037, US

(73) Assignee: SAMSUNG ELECTRONICS CO., LTD.

(21) Appl. No.: 11/582,481

(22) Filed: Oct. 18, 2006

(30) Foreign Application Priority Data
Nov. 29, 2005 (KR) 10-2005-0115058

(51) Int. Cl. H01L 29/84

(52) U.S. Cl. 257/415

(57) ABSTRACT

A torsion spring for a micro-electro-mechanical system (MEMS) structure is provided. The torsion spring is connected between a pivoting member and a fixed member and supports the pivoting member so that the pivoting member can pivot about the torsion spring. The torsion spring includes: a horizontal beam; at least one vertical beam formed on the horizontal beam; and a plurality of auxiliary beams formed on the horizontal beam and parallel to the vertical beam.

### CROSS-REFERENCE TO RELATED PATENT APPLICATION

This application claims priority from of Korean Patent Application No. 10-2005-0115058, filed on Nov. 29, 2005, in the Korean Intellectual Property Office, the disclosure of which is incorporated herein in its entirety by reference.

### BACKGROUND OF THE INVENTION

1. Field of the Invention

The present invention relates to a torsion spring for a micro-electro-mechanical system (MEMS) structure, and more particularly, to a torsion spring with a great ratio of bending stiffness to torsion stiffness.

2. Description of the Related Art

Micro-electro-mechanical system (MEMS) structures are built using a semiconductor process. In general, MEMS structures include a stage suspended above a substrate and torsion springs that support both sides of the stage so that the stage can seesaw about the torsion springs. MEMS structures can be applied to, among other things, MEMS gyroscopes, optical scanners of flat panel displays, or the like.

The torsion springs should make the stage or a driving frame pivot only in a specific direction. To this end, the torsion springs should have a great ratio of bending stiffness to torsion stiffness, a resistance to deformation in a direction perpendicular to the axis of rotation, and a resistance to torsion around the axis of torsion.

Torsion springs used for macro structures can have a great ratio of bending stiffness to torsion stiffness by being manufactured to have a circular or cross-shaped section. However, this approach is difficult to be applied to torsion springs used for MEMS structures and requires many additional processes.

FIG. 1 is a perspective view of a conventional torsion spring 10 for a MEMS structure, which has a beam shape with a rectangular section. Referring to FIG. 1, bending stiffness and torsion stiffness of the conventional torsion spring 10 are determined by a ratio of width b₀ to length L₀ and a ratio of width b₀ to height h₀ of the beam. For example, when the ratio of the length L₀ increases, both the bending stiffness and the torsion stiffness decrease. Accordingly, it is difficult to increase the ratio of the bending stiffness to the torsion stiffness for the conventional torsion spring 10 constructed as shown in FIG. 1.

To solve this problem, Lilac Muller, Albert P. Pisano, and Roger T Howe suggested in “Microgimbal Torsional Beam Design Using Open, Thin-Walled Cross Section” Journal of MEMS, Vol. 10, NO. 4, December 2001, a torsion spring 20 as shown in FIG. 2. The torsion spring 20 has a horizontal beam 23 that is formed on top surfaces of a pair of parallel vertical beams 21 to connect the vertical beams 21. The torsion spring 20 can significantly increase the bending stiffness without a substantial increase of the torsion stiffness. However, it is difficult to form a trench with a predetermined width and depth using etch lag during an etching process of the torsion spring 20 of FIG. 2 .

### SUMMARY OF THE INVENTION

The present invention provides a torsion spring for a MEMS structure, which can be simply manufactured to have a great ratio of bending stiffness to torsion stiffness.

According to an aspect of the present invention, there is provided a torsion spring for a MEMS structure, in which the torsion spring is connected between a pivoting member and a fixed member and supporting the pivoting member so that the pivoting member can pivot about the torsion spring, the torsion spring comprising: a horizontal beam; at least one vertical beam formed on the horizontal beam; and a plurality of auxiliary beams formed on the horizontal beam and parallel to the vertical beam.

The auxiliary beam may have a plate shape extending in a longitudinal direction of the horizontal beam.

The auxiliary beam may have a bar shape formed along a longitudinal direction of the horizontal beam.

The vertical beam may be formed at the center of the horizontal beam, and the auxiliary beams may be formed at both sides of the vertical beam.

The vertical beam may be a pair of vertical beams formed on both edges of the horizontal beam, and the auxiliary beam may be formed between the vertical beams.

The vertical beam may be a pair of vertical beams spaced apart from both edges of the horizontal beam, and the auxiliary beam may be formed at both sides of the vertical beams.

The vertical beam may be three vertical beams formed at regular intervals on the horizontal beam, and the auxiliary beam may be formed between the vertical beams.

According to another aspect of the present invention, there is provided a torsion spring for a MEMS structure, wherein the torsion spring is connected between a pivoting member and a fixed member and supporting the pivoting member so that the pivoting member can pivot about the torsion spring, the torsion spring comprising: a horizontal beam; an upper vertical beam and a lower vertical beam formed on top and bottom surfaces of the horizontal beam, respectively, to correspond to each other; and a plurality of upper and lower auxiliary beams formed on the top and bottom surfaces of the horizontal beam and parallel to the upper and lower vertical beam, respectively.

The horizontal beam may be a stack comprising a first conductive layer, an insulating layer, and a second conductive layer.

### BRIEF DESCRIPTION OF THE DRAWINGS

The above and other features and aspects of the present invention will become more apparent by describing in detail exemplary embodiments thereof with reference to the attached drawings in which:

FIG. 1 is a perspective view of a conventional torsion spring for a MEMS structure;

FIG. 2 is a perspective view of another conventional torsion spring for a MEMS structure;

FIG. 3 is a perspective view of a torsion spring for a MEMS structure according to an exemplary embodiment of the present invention;

FIG. 4 is a perspective view of a modification of the torsion spring of FIG. 3;

FIGS. 5A through 5D are sectional views of other modifications of the torsion spring of FIG. 3;

FIG. 6 is a perspective view of an optical scanner having a torsion spring of an exemplary embodiment of the present invention;

FIGS. 7A through 7C are perspective views illustrating a method of manufacturing the torsion spring of FIG. 3;

FIG. 8 is a perspective view of a torsion spring according to another exemplary embodiment of the present invention;

FIGS. 9A through 9D are perspective views illustrating a method of manufacturing the torsion spring of FIG. 8; and

FIGS. 10A through 10D are sectional views of a modification of the torsion spring of FIG. 8.

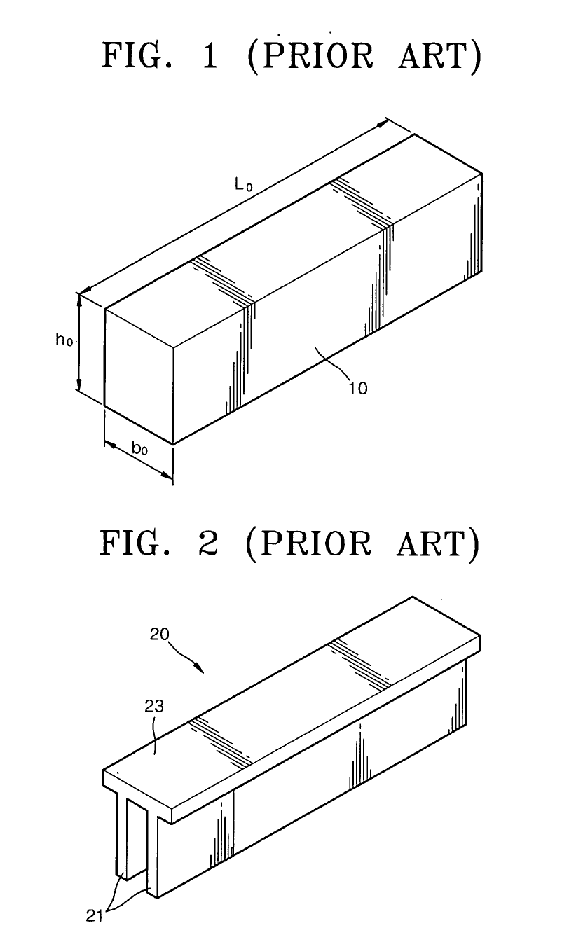

### DETAILED DESCRIPTION OF EXEMPLARY EMBODIMENTS OF THE INVENTION

The present invention will now be described more fully with reference to the accompanying drawings, in which exemplary embodiments of the invention are shown. The described exemplary embodiments are intended to assist the understanding of the invention, and are not intended to limit the scope of the invention in any way. The thickness of layers and regions shown in the drawings may be exaggerated for clarity.

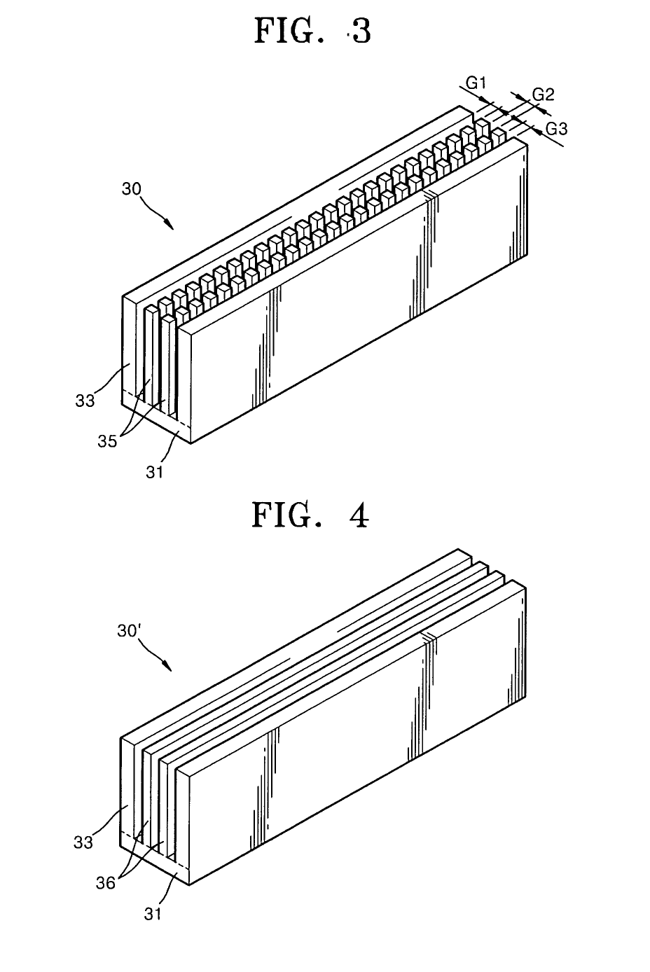

FIG. 3 is a perspective view of a torsion spring for a MEMS structure according to an exemplary embodiment of the present invention.

Referring to FIG. 3, a torsion spring 30 includes a pair of vertical beams 33, a horizontal beam 31 formed on bottom surfaces of the vertical beams 33 to connect the vertical beams 33, and a plurality of auxiliary beams 35 perpendicularly formed on the horizontal beam 31. Although the horizontal beam 31, the vertical beams 33, and the auxiliary beams 35 are integrally formed, they are given different reference numerals for convenience of explanation.

The horizontal beam 31 and the vertical beams 33 extend in a longitudinal direction of the torsion spring 30. The horizontal beam 31 and the vertical beams 33 have plate shapes with a rectangular section. The auxiliary beams 35 may have rectangular bar shapes. The horizontal beam 31 and the vertical beams 33 are perpendicular to each other. Ends of the horizontal beam 31 and the vertical beams 33 are connected to predetermined portions on a substrate (not shown), for example, connected between a fixed member like an anchor and a pivoting member like a stage.

A gap G2 between the auxiliary beams 35, a gap GI between one of the pair of vertical beams 33 and the auxiliary beams 35, and a gap G3 between the other of the pair of vertical beams 33 and the auxiliary beams 35 may be formed to have micrometer dimensions, and cause etch lag during an etching process. The etch lag enables the horizontal beam 31 to be formed.

FIG. 4 is a perspective view of a modification of the torsion spring 30 of FIG. 3. Reference numerals identical to those in FIG. 3 denote like elements, and a detailed description of these elements will not be repeated.

Referring to FIG. 4, auxiliary beams 36 formed between the vertical beams 33 have plate shapes and extend in a longitudinal direction of a torsion spring 30′, similarly to the vertical beams 33 and the horizontal beam 31.

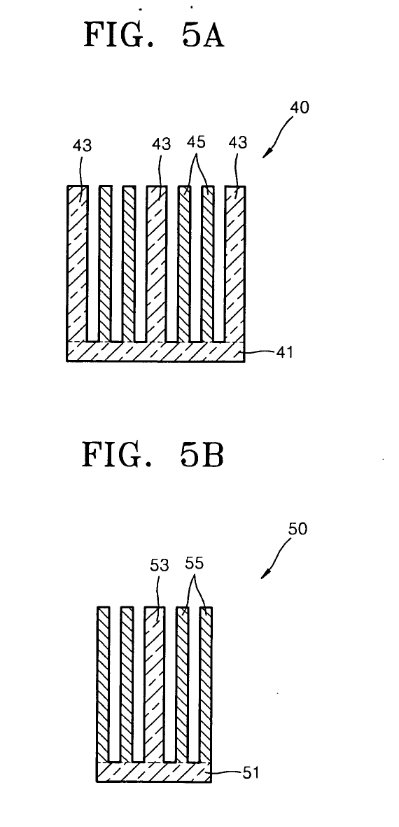

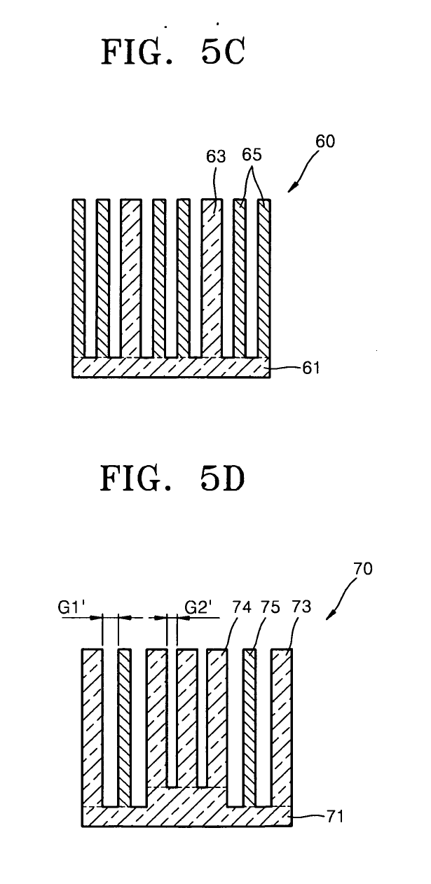

FIGS. 5A through 5D are sectional views of other modifications of the torsion spring 30 of FIG. 3.

Referring to FIG. 5A, a torsion spring 40 includes a horizontal beam 41, three vertical beams 43 perpendicularly formed on the horizontal beam 41 and spaced at regular intervals from one another, and auxiliary beams 45 formed on the horizontal beam 41 between the vertical beams 43. The auxiliary beams 45 may have plate shapes or bar shapes parallel to the vertical beams 43.

Referring to FIG. 5B, a torsion spring 50 includes a horizontal beam 51, a vertical beam 53 perpendicularly formed on the horizontal beam 51, and auxiliary beams 55 formed on the horizontal beams 51 at both sides of the vertical beam 53.

Referring to FIGS. 5C, a torsion spring 60 includes a horizontal beam 61, two vertical beams 63 formed on the horizontal beam 61 and spaced apart from both edges of the horizontal beam 61, and auxiliary beams 65 formed on the horizontal beam 61.

Referring to FIG. 5D, a torsion spring 70 includes a horizontal beam 71, two first vertical beams 73 perpendicularly formed on both ends of the horizontal beam 71, three second vertical beams 74 formed between the first vertical beams 73, and auxiliary beams 75 formed between the first and second vertical beams 73 and 74. A gap Gi′ between the auxiliary beams 75 and each of the vertical beams 73 and 74 is greater than a gap G2′ between the second vertical beams 74, and thus a depth of a trench formed due to the gap G2′ is smaller than a depth of a trench formed due to the gap G1′. These depths can be adjusted by controlling the widths of the gaps Gi′ and G2′.

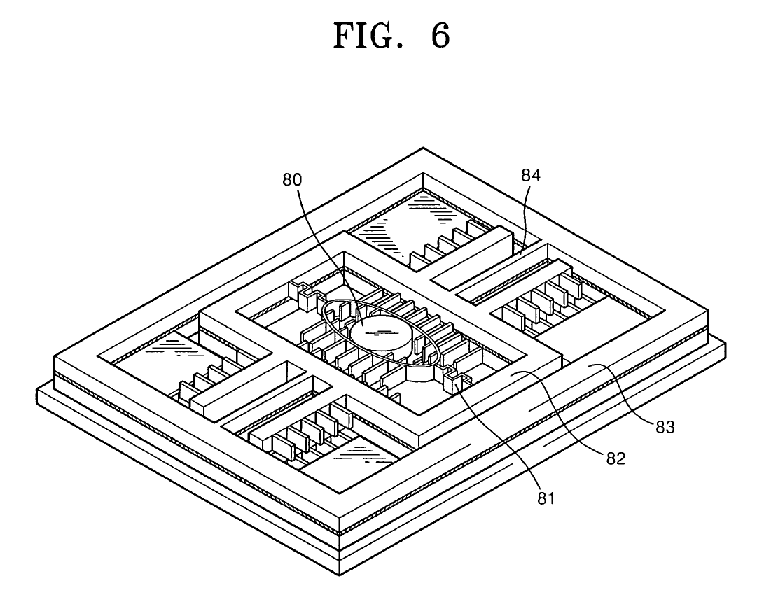

FIG. 6 is a perspective view of an optical scanner having a torsion spring according to an exemplary embodiment of the present invention. A general description of the type of optical scanner such as that shown in FIG. 6 is provided in U.S. Patent Application Publication No. 2006/0082250, which is hereby incorporated by reference in its entirety.

Referring to FIG. 6, an optical scanner includes a first torsion spring 81 connected between a stage 80 and a driving frame 82, and a second torsion spring 84 connected between the driving frame 82 and a fixed frame 83. Each of the first and second torsion springs 81 and 84 may have a similar structure to a torsion spring of one of the exemplary embodiments of the present invention. Because the first and second torsion springs 81 and 84 are structured according to one of the exemplary embodiments of the present invention, the torsion springs of the optical scanner of FIG. 6 have good bending stiffness. The horizontal beam can be easily formed using etch lag of the auxiliary beams when the stage 80, the driving frame 82, the fixed frame 83, and the vertical beams of the torsion spring of an exemplary embodiment of the present invention are formed.

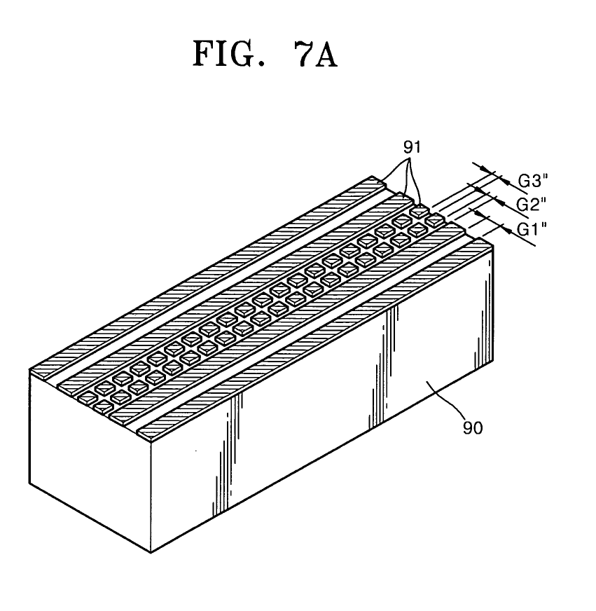

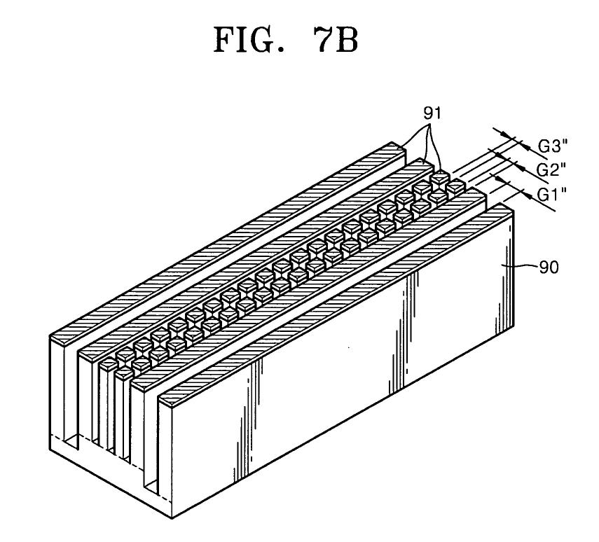

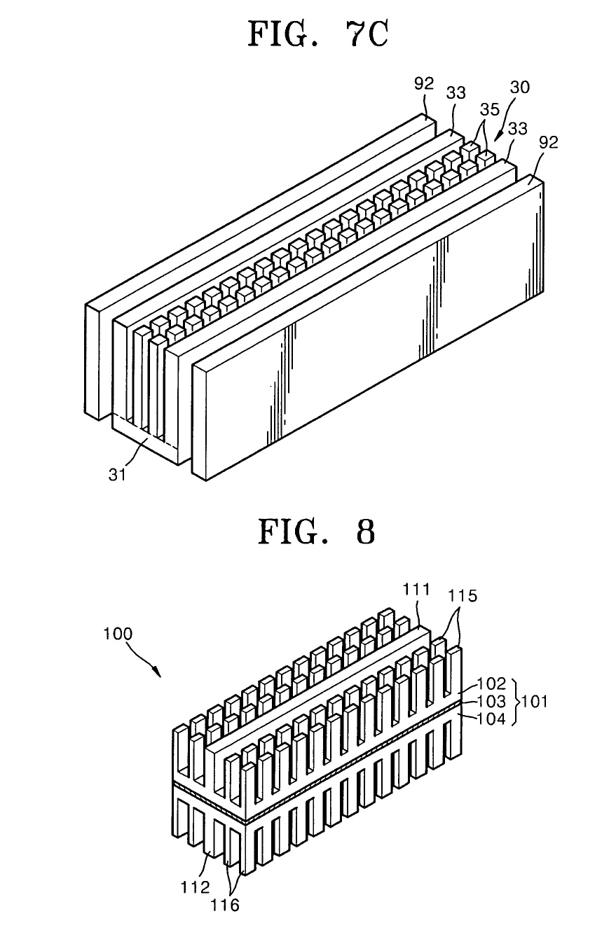

FIGS. 7A through 7C are perspective views illustrating a method of manufacturing the torsion spring 30 of FIG. 3.

Referring to FIG. 7A, an insulating mask 91 is formed on a silicon substrate 90. At this time, a gap G1″ between a vertical beam portion and a frame portion should be greater than each of a gap G2″ between the vertical beam portion and an auxiliary beam portion and a gap G3″ between the auxiliary beams 35.

Referring to FIG. 7B, when areas not covered by the mask 91 are etched in a reactive ion etching (RIE) process, an etch rate of the gap G1″ is faster than that of each of the gaps G2″ and G3″ because the gap G1″ is greater than each of the gaps G2″ and G3″.

Referring to FIG. 7C, after the etching process is performed for a predetermined period of time, the frame portion and the vertical portion are completely separated from each other by the gap G1″ to form a frame 92 and the torsion spring 30. The torsion spring 30 includes the vertical beams 33 and the auxiliary beams 35 formed on the horizontal beam 31.

FIG. 8 is a perspective view of a torsion spring 100 according to another exemplary embodiment of the present invention.

Referring to FIG. 8, the torsion spring 100 includes a horizontal beam 101, upper and lower vertical beams 111 and 112 perpendicularly formed at centers of top and bottom surfaces of the horizontal beam 101, respectively, to correspond to each other, and upper and lower auxiliary beams 115 and 116 perpendicularly formed on the horizontal beam 101 such that the upper auxiliary beams 115 are disposed at both sides of the upper vertical beam 111 and the lower auxiliary beams 116 are disposed at both sides of the lower vertical beam 112.

The horizontal beam 101 may be composed of a first conductive layer 102, an insulating layer 103, and a second conductive layer 104. The horizontal beam 101 may be manufactured by etching a silicon-on-insulator (SOI) substrate. In this case, the torsion spring 100 fabricated using the multi-layered silicon substrate can have paths through which voltages are separately applied to upper comb electrodes and lower comb electrodes as shown in FIG. 6.

The auxiliary beams 115 and 116 cause etch lag such that the first and second conductive layers 102 and 104 can be formed while the other elements, such as the frame 92 in FIG. 7C, are formed as described above.

The torsion spring 100 constructed as above is configured in a ribbed structure, thereby increasing bending stiffness.

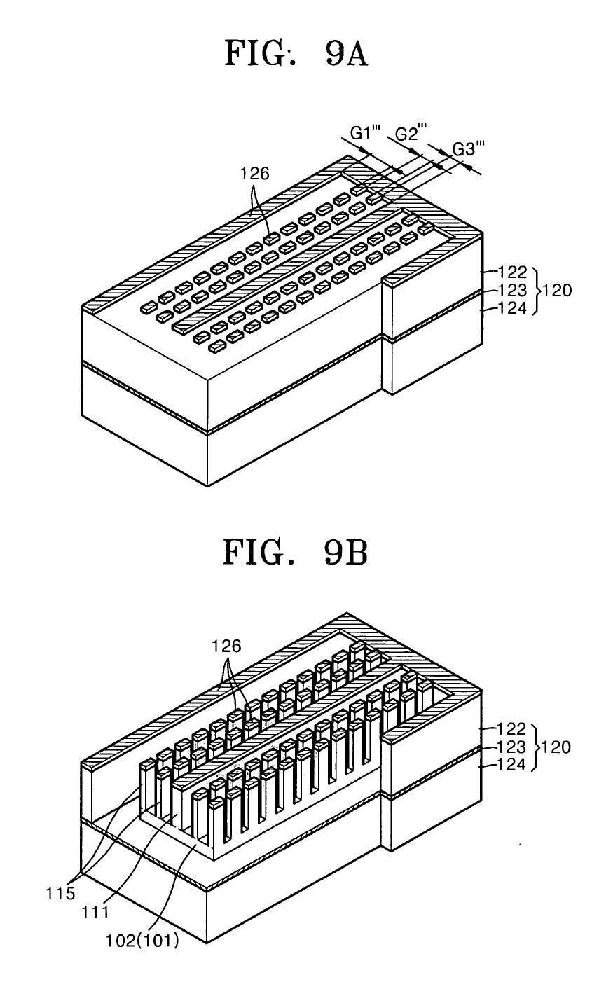

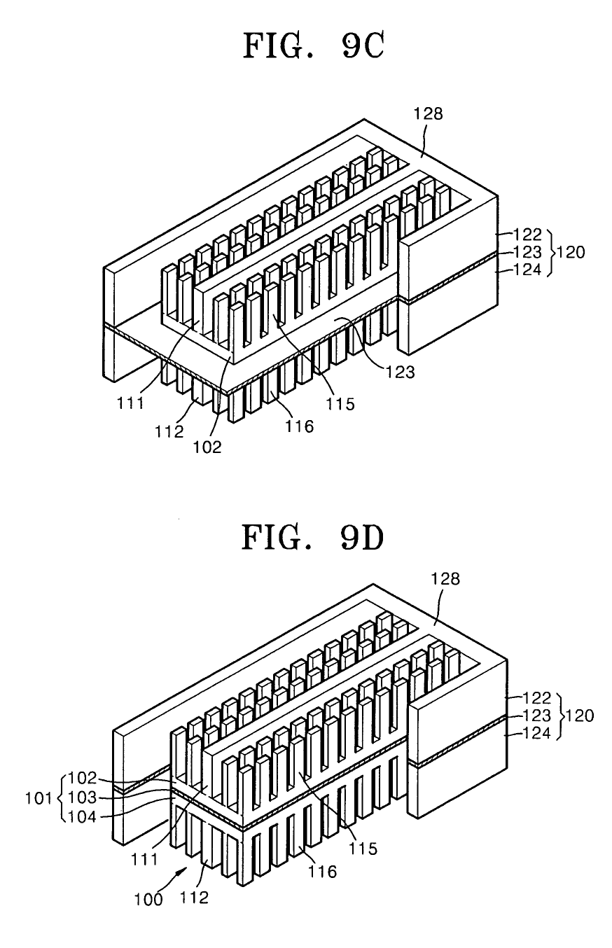

FIGS. 9A through 9D are perspective views illustrating a method of manufacturing the torsion spring 100 of FIG. 8. Reference numerals identical to those in FIG. 8 denote like elements, and a detailed description of the elements will not be repeated.

Referring to FIG. 9A, an SOI substrate 120 is prepared. A frame to which the torsion spring 100 is connected is partially illustrated for convenience of explanation. The substrate 120 is formed by stacking a first conductive layer 122 made of silicon, an insulating layer 123 made of silicon oxide, and a second conductive layer 124 made of silicon. Next, a mask 126 is formed on the first conductive layer 122. Here, a gap G1′″ between an auxiliary beam portion and a frame portion is greater than each of a gap G3′″. between a vertical beam portion and the auxiliary beam portion and a gap G2′″ between auxiliary beam portions.

Referring to FIG. 9B, when areas not covered by the mask 126 are etched in an RIE process, an etch rate of the gap G1′″ is faster than that of each of the gaps G2′″ and G3′″. Accordingly, while the gap G1′″ is etched to the insulating layer 123 that is used as an etch stop layer, etch lag occurs at the gaps G2′″ and G3′″ to form the first conductive layer 102 of the horizontal beam 101, the vertical beam 111, and the auxiliary beams 115 on the first conductive layer 102.

Referring to FIG. 9C, the second conductive layer 124 of the substrate 120 is etched to form the vertical beam 112 and the auxiliary beams 116 respectively corresponding to the vertical beam 111 and the auxiliary beams 115 formed at the first conductive layer 122 of the substrate 120.

Referring to FIG. 9D, an exposed portion of the insulating layer 123 is etched to form the torsion spring 100 and the frame 128.

Although the upper and lower auxiliary beams 115 and 116 have bar shapes in the present exemplary embodiment, the present invention is not limited thereto. That is, the upper and lower auxiliary beams 115 and 116 may have plate shapes like the upper and lower vertical beams 111 and 112.

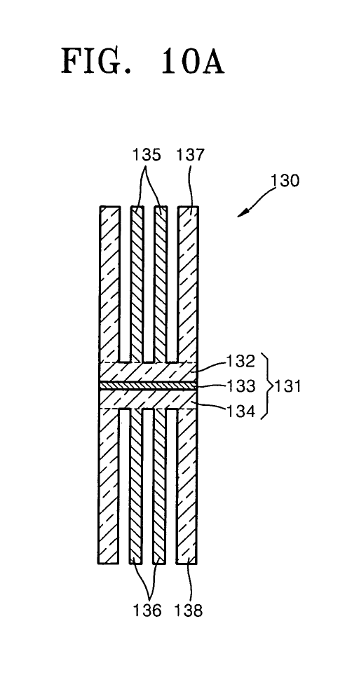

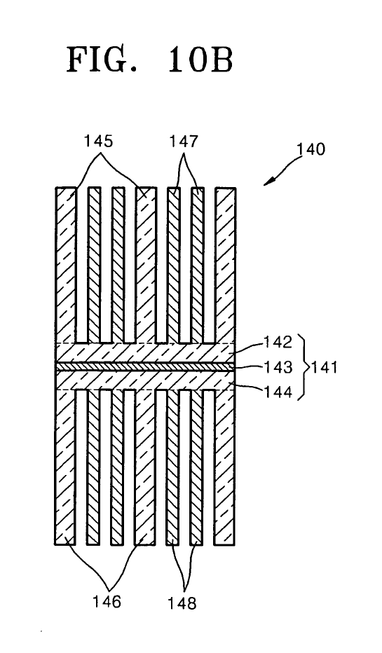

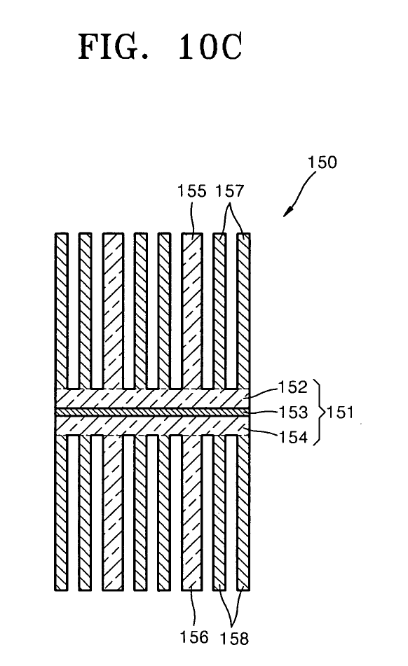

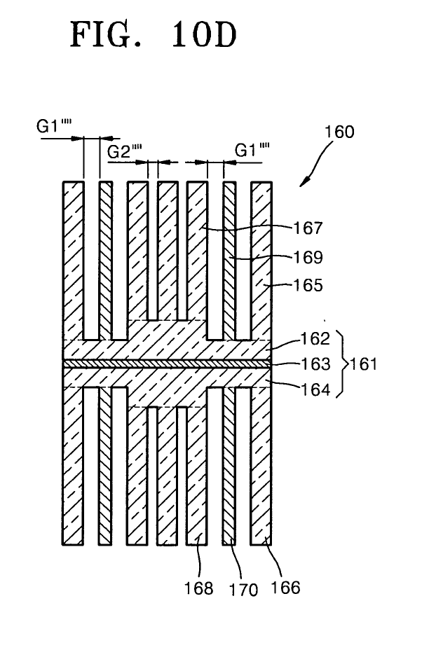

FIGS. 10A through 10D are sectional views of modifications of the torsion spring 100 of FIG. 8.

Referring to FIG. 10A, a torsion spring 130 includes a horizontal beam 131, upper and lower vertical beams 137 and 138 perpendicularly formed on both edges of top and bottom surfaces of the horizontal beam 131, respectively, to correspond to each other, and upper and lower auxiliary beams 135 and 136 perpendicularly formed on the top and bottom surfaces of the horizontal beam 131, respectively, such that the upper auxiliary beams 135 are disposed between the upper vertical beams 137 and the lower auxiliary beams 136 are disposed between the lower vertical beams 138. The torsion spring 130 has an “H” shape, and accordingly the horizontal beam 131 increases the bending stiffness of the torsion spring 130.

The horizontal beam 131 may be composed of a first conductive layer 132, an insulating layer 133, and a second conductive layer 134.

Referring to FIG. 10B, a torsion spring 140 includes a horizontal beam 141, upper and lower vertical beams 145 and 146 perpendicularly formed on top and bottom surfaces of the horizontal beam 141, respectively, to correspond to each other, and upper and lower auxiliary beams 147 and 148 perpendicularly formed on the top and bottom surfaces of the horizontal beam 141 such that the upper auxiliary beams 147 are disposed between the upper vertical beams 145 and the lower auxiliary beams 148 are disposed between the lower vertical beams 146. The horizontal beam 141 may be composed of a first conductive layer 142, an insulating layer 143, and a second conductive layer 144.

Referring to FIG. 10C, a torsion spring 150 includes a horizontal beam 151, two upper and lower vertical beams 155 and 156 perpendicularly formed on top and bottom surfaces of the horizontal beam 151, respectively, to correspond to each other and be spaced apart from both edges of the horizontal beam 151, and upper and lower auxiliary beams 157 and 158 perpendicularly formed on the top and bottom surfaces of the horizontal beam 151. The horizontal beam 151 may be composed of a first conductive layer 152, an insulating layer 153, and a second conductive layer 154.

Referring to FIG. 10D, a torsion spring 160 includes a horizontal beam 161, two first upper and lower vertical beams 165 and 166 perpendicularly formed on top and bottom surfaces of the horizontal beam 161 to be disposed on both sides of the top and bottom surfaces of the horizontal beam 161, three second upper and lower vertical beams 167 and 168 formed such that the second upper vertical beams 167 are disposed between the first upper vertical beams 165 and the second lower vertical beams 168 are disposed between the first lower vertical beams 166, and upper and lower auxiliary beam 169 and 170 formed such that the upper auxiliary beams 169 are disposed between the first upper vertical beams and the second upper vertical beam 167 and the lower auxiliary beams 170 are disposed between the first lower vertical beams 166 and the second lower vertical beams 168. A gap G1″″ between the auxiliary beam 169 and 170 and each of the first and second vertical beams 165, 166 and 167, 168 is greater than a gap G2′″ between the second vertical beams 167 and 168, and thus a depth of a trench formed due to the gap G2′″ is less than a depth of a trench formed due to the gap G1′″. The horizontal beam 161 may be composed of a first conductive layer 162, an insulating layer 163, and a second conductive layer 164.

As described above, the torsion spring for a MEMS structure according to exemplary embodiments of the present invention has increased bending stiffness due to the horizontal beam. Also, the horizontal beam of the torsion spring of the exemplary embodiments of the present invention can be easily formed using etch lag that occurs at the region where the trench is narrow.

While the present invention has been particularly shown and described with reference to exemplary embodiments thereof, it will be understood by those of ordinary skill in the art that various changes in form and details may be made therein without departing from the spirit and scope of the present invention as defined by the following claims.

What is claimed is:

1. A torsion spring for a micro-electro-mechanical system (MEMS) structure, in which the torsion spring is connected between a pivoting member and a fixed member and supports the pivoting member so that the pivoting member can pivot about the torsion spring, the torsion spring comprising:
a horizontal beam;
at least one vertical beam formed on the horizontal beam; and
a plurality of auxiliary beams formed on the horizontal beam and parallel to the vertical beam.

2. The torsion spring of claim 1, wherein the auxiliary beams are plate-shaped extending in a longitudinal direction of the horizontal beam.

3. The torsion spring of claim 1, wherein the auxiliary beams comprise a plurality of bars formed along in a longitudinal direction of the horizontal beam.

4. The torsion spring of claim 1, wherein the vertical beam is formed at the center of the horizontal beam, and the auxiliary beams are formed at opposite sides of the vertical beam.

5. The torsion spring of claim 1, wherein the at least one vertical beam comprises a pair of vertical beams formed on opposite edges of the horizontal beam, and the auxiliary beams are formed between the vertical beams.

6. The torsion spring of claim 1, wherein the at least one vertical beam comprises a pair of vertical beams spaced apart from opposite edges of the horizontal beam, and the auxiliary beams are formed at both sides of each of the vertical beams.

7. The torsion spring of claim 1, wherein the at least one vertical beam comprises three vertical beams formed at regular intervals on the horizontal beam, and the auxiliary beams are formed between the vertical beams.

8. A torsion spring for a micro-electro-mechanical system (MEMS) structure, in which the torsion spring is connected between a pivoting member and a fixed member and supports the pivoting member so that the pivoting member can pivot about the torsion spring, the torsion spring comprising:
a horizontal beam;
at least one upper vertical beam formed on a top surface of the horizontal beam and at least one lower vertical beam formed on a bottom surface of the horizontal beam; and
a plurality of upper auxiliary beams formed on the top surface of the horizontal beam and which are parallel to the upper vertical beam, and a plurality of lower auxiliary beams formed on the bottom surface of the horizontal beam and which are parallel to the lower vertical beam.

9. The torsion spring of claim 8, wherein the horizontal beam comprises a first conductive layer, an insulating layer, and a second conductive layer.

10. The torsion spring of claim 9, wherein the auxiliary beams are plate-shaped and extend in a longitudinal direction of the horizontal beam.

11. The torsion spring of claim 9, wherein the auxiliary beams comprise a plurality of bars formed along a longitudinal direction of the horizontal beam.

12. The torsion spring of claim 9, wherein the upper vertical beam is formed at the center of the first conductive layer and the lower vertical beam is formed at the center of the second conductive layer, and the upper auxiliary beams are formed at both of two opposite sides of the upper vertical beam and the lower auxiliary beams are formed at both of two opposite sides of the lower vertical beam.

13. The torsion spring of claim 9, wherein the vertical beams comprise two upper vertical beams formed on opposite edges of the first conductive layer and two lower vertical beams formed on opposite edges of the second conductive layer, and the upper auxiliary beams are formed between the upper vertical beams and the lower auxiliary beams are formed between the lower vertical beams.

14. The torsion spring of claim 9, wherein the vertical beams comprise two upper vertical beams spaced apart from opposite edges of the first conductive layer and two lower vertical beams spaced apart from opposite edges of the second conductive layer, and the upper auxiliary beams are formed at both of two opposite sides of the upper vertical beams and the lower auxiliary beams are formed at both of two opposite sides of the lower vertical beams.

15. The torsion spring of claim 9, wherein the vertical beams comprise three upper vertical beams formed at regular intervals on the first conductive layer and three lower vertical beams formed at regular intervals on the second conductive layer, and the upper auxiliary beams are formed between the upper vertical beams and the lower auxiliary beams are formed between the lower vertical beams.

16. The torsion spring of claim 8, wherein the location of the at least one upper vertical beam corresponds to the location of the at least one lower vertical beam.

17. A micro-electro-mechanical system (MEMS) structure comprising:
a fixed member;
a pivoting member; and
a torsion spring connected between the fixed member and the pivoting member;
wherein the torsion spring comprises:
a horizontal beam;
at least one vertical beam formed on the horizontal beam; and
a plurality of auxiliary beams formed on the horizontal beam and parallel to the vertical beam.

18. The MEMS structure of claim 17, wherein the at least one vertical beam comprises at least one upper vertical beam formed on a top surface of the horizontal beam and at least one lower vertical beam formed on a bottom surface of the horizontal beam; and
the plurality of auxiliary beams comprises a plurality of upper auxiliary beams formed on the top surface of the horizontal beam and which are parallel to the at least one upper vertical beam and a plurality of lower auxiliary beams formed on the bottom surface of the horizontal beam and which are parallel to the lower vertical beam.

19. A method of manufacturing a torsion spring and a frame, the torsion spring comprising a horizontal beam, at least one vertical beam and a plurality of auxiliary beams, the method comprising:
providing a substrate;
forming an insulating mask on the substrate such that a gap between a vertical beam portion, at which the vertical beam is to be formed, and a frame portion, at which the frame is to be formed, is greater than a gap between the vertical beam portion and an auxiliary beam portion, at which the auxiliary beams are to be formed, and a gap between the auxiliary beams of the auxiliary beam portion;
etching the unmasked areas.

20. A method of manufacturing a torsion spring and a frame, the torsion spring comprising a horizontal beam, at least one upper vertical beam, at least one lower vertical beam and a plurality of upper and lower auxiliary beams, the method comprising:
providing a substrate comprising a first conductive layer, a second conductive layer and an insulating layer formed between the first conductive layer and the second conductive layer;
forming an insulating mask on the first conductive layer such that a gap between an upper vertical beam portion, at which the upper vertical beam is to be formed, and a frame portion, at which the frame is to be formed, is greater than a gap between the upper vertical beam portion and an upper auxiliary beam portion, at which the upper auxiliary beams are to be formed, and a gap between the upper auxiliary beams of the upper auxiliary beam portion; and
etching the unmasked areas.

21. The method of manufacturing a torsion spring and a frame according to claim 20 further comprising:
forming an insulating mask on the second conductive layer such that a gap between a lower vertical beam portion, at which the lower vertical beam is to be formed, and a frame portion, at which the frame is to be formed, is greater than a gap between the lower vertical beam portion and a lower auxiliary beam portion, at which the lower auxiliary beams are to be formed, and a gap between the lower auxiliary beams of the lower auxiliary beam portion; and
etching the unmasked areas.

22. The method of manufacturing a torsion spring and a frame according to claim 21 further comprising:
etching an exposed portion of the insulating layer to form the torsion spring and the frame.
